(19) United States
(12) Patent Application Publication
(10) Pub. No.: US 2026/0244068 A1
(43) Pub. Date: Aug. 20, 2026

(54) METHOD FOR CONTROLLING REFRACTIVE INDEX OF PLANAR WAVEGUIDE

(71) Applicant: Dispelix OY, Espoo (FI)

(72) Inventor: Klas ANDERSSON, Espoo (FI)

(73) Assignee: Dispelix OY, Espoo (FI)

(21) Appl. No.: 19/134,196

(22) PCT Filed: Nov. 15, 2023
(86) PCT No.: PCT/FI2023/050631

§ 371 Date: May 29, 2025

(30) Foreign Application Priority Data
Dec. 8, 2022 (FI) 20226082

(51) Int. Cl. G02F 1/19; G02B 27/01; G02F 1/01

(52) U.S. Cl. CPC G02F 1/19; G02B 27/0172; G02F 1/011; G02F 1/0126; G02F 1/0147; G02F 2201/305

(57) ABSTRACT

According to an embodiment, a method for controlling a refractive index of a planar waveguide comprises: providing a planar waveguide comprising a plurality of area segments; and controlling a refractive index of the plurality of area segments of the planar waveguide by exposing the planar waveguide to a plurality of electromagnetic radiation exposures corresponding to the plurality of area segments and/or exposing the planar waveguide to a plurality of heat exposures corresponding to the plurality of area segments.

### TECHNICAL FIELD

The present disclosure relates to the field of optics, and more particularly to a method for controlling a refractive index of a planar waveguide, a display structure, and a display device.

### BACKGROUND

Many optical properties of a waveguide are controlled by the refractive index of the waveguide. Thus, it may be desirable to be able to control and/or modify the refractive index of a waveguide over the geometry of the waveguide.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an object to provide a method for controlling a refractive index of a planar waveguide, a display structure, and a display device. The foregoing and other objects are achieved by the features of the independent claims. Further implementation forms are apparent from the dependent claims, the description and the figures.

According to a first aspect, a method for controlling a refractive index of a planar waveguide comprises: providing a planar waveguide comprising a plurality of area segments; and controlling a refractive index of the plurality of area segments of the planar waveguide by exposing the planar waveguide to a plurality of electromagnetic radiation exposures corresponding to the plurality of area segments and/or exposing the planar waveguide to a plurality of heat exposures corresponding to the plurality of area segments.

According to second aspect, a display structure comprises a planar waveguide obtained by the method according to the first aspect.

According to a third aspect, a display device comprises the display structure according to the second aspect.

Many of the attendant features will be more readily appreciated as they become better understood by reference to the following detailed description considered in connection with the accompanying drawings.

### DESCRIPTION OF THE DRAWINGS

In the following, example embodiments are described in more detail with reference to the attached figures and drawings, in which:

FIG. 1 illustrates a flow chart representation of a method according to an embodiment;

FIG. 2 illustrates a cross-sectional representation of a planar waveguide according to an embodiment;

FIG. 3 illustrates a schematic representation of a planar waveguide comprising at least one diffractive grating according to an embodiment;

FIG. 4 illustrates a cross-sectional representation of a planar waveguide comprising a diffractive grating according to an embodiment;

FIG. 5 illustrates a schematic representation of a display structure according to an embodiment; and

FIG. 6 illustrates a schematic representation of a display device according to an embodiment.

In the following, identical reference signs refer to similar or at least functionally equivalent features.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilised, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

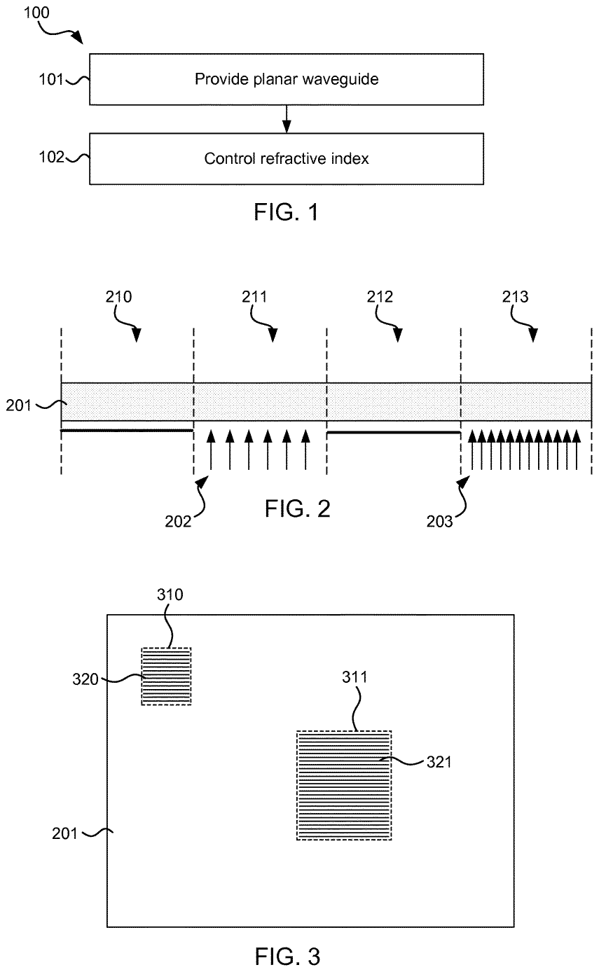

FIG. 1 illustrates a flow chart representation of a method according to an embodiment.

According to an embodiment, a method 100 for controlling a refractive index of a planar waveguide comprises providing 101 a planar waveguide comprising a plurality of area segments.

The controlling the refractive index of the planar waveguide may also be referred to as modifying the refractive index of the planar waveguide, adjusting the refractive index of the planar waveguide, adapting the refractive index of the planar waveguide, or similar.

The method 100 may further comprise controlling 102 a refractive index of the plurality of area segments of the planar waveguide by exposing the planar waveguide to a plurality of electromagnetic radiation exposures corresponding to the plurality of area segments and/or exposing the planar waveguide to a plurality of heat exposures corresponding to the plurality of area segments.

Herein, an exposure may refer to, for example, a total amount of radiation energy and/or heat energy per unit area the planar waveguide is exposed to. The exposure may be controlled by, for example, controlling the intensity/power/brightness/luminance/wave-length/frequency of the electromagnetic radiation and/or the length of time each area segment is exposed to the radiation.

Exposure may also be referred to as a dose, electromagnetic radiation dose, electromagnetic radiation exposure, or similar.

In some embodiments, each area segment in the plurality of area segments may be exposed to a different electromagnetic radiation exposure and/or heat exposure. In some other embodiments, some area segments in the plurality of area segments may be exposed to the same electromagnetic radiation exposure and/or heat exposure.

The planar waveguide may be made of, for example, high refractive index glasses. Further, other substances, such as those disclosed herein, may be incorporated into the planar waveguide.

The refractive index of the planar waveguide and/or the change in the refractive index of the planar waveguide may be wavelength dependent. For example, the change in the refractive index may be least significant for wavelengths correspond to the colour red and most significant for wavelengths correspond to the colour blue.

The controlling 102 the refractive index of the plurality of area segments of the planar waveguide may comprise controlling the refractive index at least for visible wavelengths of light. Herein, visible wavelengths of light may refer to the wavelength range 380-750 nanometres (nm).

According to an embodiment, the electromagnetic radiation comprises ultraviolet (UV) radiation and/or infrared (IR) radiation.

The method 100 may be able to control the refractive index of the area segments of the planar waveguide. The possibility to control/adjust the refractive index over the planar waveguide can enable new waveguide design options and/or solve present waveguide design issues.

FIG. 2 illustrates a cross-sectional representation of a planar waveguide according to an embodiment.

According to an embodiment, the exposing the planar waveguide to the plurality of electromagnetic radiation exposures corresponding to the plurality of area segments and/or the exposing the planar waveguide to the plurality of heat exposures corresponding to the plurality of area segments comprises at least one of: masking at least one area segment of the plurality of area segments; varying an intensity of the electromagnetic radiation between the plurality of area segments; varying an intensity of the heat between the plurality of area segments; and/or varying a wavelength of the electromagnetic radiation between the plurality of area segments.

A planar waveguide 201 may refer to a waveguide the dimensions of which are significantly greater in two directions than in the third directions. The two directions may be referred to as width directions or similar. The third direction may be referred to as a thickness direction or similar. For example, dimensions of the planar waveguide 201 may be centimetres or tens of centimetres in the width directions and less than a centi-metre in the thickness direction.

In some embodiment, the planar waveguide 201 may have a curved shape. For example, the planar waveguide 201 may correspond to a lens of smart glasses, a windshield, a visor, such as a helmet visor, or similar.

Herein, an area segment of a planar waveguide 201 may refer to a segment/section/part of the waveguide when viewed along the thickness direction. Thus, each area segment may be bounded in the width directions and may encompass the whole planar waveguide in the thickness direction. For example in the embodiment of FIG. 2, each of the area segments 210-213 is bounded in one of the two width directions and encompasses the whole planar waveguide 201 in the thickness direction. In the other direction of the two width directions, which is not illustrated in the embodiment of FIG. 2, since the direction corresponds to the depth direction from the point of view used in FIG. 2, each area segment 210 213 may be bounded by the corresponding dimension of the planar waveguide 201 along that direction. Thus, the each area segment 210-213 in the embodiment of FIG. 2 may correspond to a “slice” of the planar waveguide 201.

For example, in the embodiment of FIG. 2, the plurality of area segments comprises four area segments 210-213. A first area segment 210 and a third area segment 212 are masked. Thus, the first area segment 210 and the third area segment 212 may not be exposed to the electromagnetic radiation. Further, a second area segment 211 is exposed to a first intensity of electromagnetic radiation 202, and a fourth area segment 213 is exposed to a second intensity of electromagnetic radiation 203.

The area segments 210-213 illustrated in the embodiment of FIG. 2 are only simplified examples and the plurality of area segments may be arranged in various other ways.

According to an embodiment, the planar waveguide 201 comprises a substance sensitive to the electromagnetic radiation and/or to the heat and/or a coating sensitive to the electromagnetic radiation and/or to the heat.

Herein, the substance may also be referred to as an alloying, a dopant, or similar.

For example, the coating sensitive to the electromagnetic radiation and/or to the heat may be on at least one surface of the planar waveguide 201.

Herein, a substance sensitive to the electro-magnetic radiation and/or to the heat or a coating sensitive to the electromagnetic radiation and/or to the heat may refer to a substance/coating that can cause the refractive index of the planar waveguide 201 to change when the substance/coating in/on the planar waveguide 201 is exposed to the electromagnetic radiation and/or to the heat.

According to an embodiment, the electromagnetic radiation comprises ultraviolet (UV) radiation and the substance and/or the coating comprises at least one of: titanium dioxide (TiO₂), germanium dioxide (GeO₂), germanium (Ge), and/or boron (B).

In some embodiments, the planar waveguide comprises 1-30 weight percentage (w %) of Ti₂, 5-25 w % of TiO₂, or 10-20 w % of TiO₂.

At least some of the aforementioned substances and/or coatings can change the refractive index of the planar waveguide when exposed to UV radiation.

The change in the refractive index may be due to, for example, the electromagnetic radiation heating the substance/coating, and the heat causing a change in the crystal structure or recrystallisation of the substance/coating. Similar change may be achieved using heat exposure.

In some embodiments, the substance may comprise microparticles and/or nanoparticles. For example, the substance may comprise TiO₂ in amorphic form, microparticles, and/or nanoparticles, GeO₂ in amorphic form, microparticles, and/or nanoparticles, Ge in amorphic form, microparticles, and/or nanoparticles, and/or B in amorphic form, microparticles, and/or nanoparticles.

According to an embodiment, dimensions of the microparticles and/or nanoparticles are in the range 1-30 nm.

Alternatively or additionally, dimensions of the microparticles and/or nanoparticles can be in the range 5-30 nm, 10-30 nm, 5-20 nm, or 1-20 nm.

In some embodiments, the microparticles and/or nanoparticles may be microspheres and/or nanospheres. Diameters of the microspheres and/or nanospheres may be in the range 1-30 nm. Alternatively or additionally, diameters of the microspheres and/or nanospheres can be in the range 5-30 nm, 10-30 nm, 5-20 nm, or 1-20 nm.

According to an embodiment, the microparticles and/or nanoparticles comprise at least one of: microspheres and/or nanospheres, microrods and/or nanorods, microcubes and/or nanocubes, core-shell particles, nanopowder particles, raspberry-like particles, and/or spike particles.

Raspberry-like particles may refer to particles that comprise substantially spherical protrusions of the surface of the particle.

Nanopowders can be defined as powdered materials with individual particles in nanometre scale or materials with crystalline in nanometre scale.

In some embodiments, the particles may comprise clusters of various shapes, such as rods and/or spikes.

In some embodiments, the microparticles and/or nanoparticles can have random shapes.

According to an embodiment, the controlling the refractive index of the plurality of area segments of the planar waveguide defines at least one refractive index gradient over the planar waveguide.

Herein, a refractive index gradient may refer to a change of a refractive index along a spatial dimension. For example, when the refractive index changes between two area segments in the plurality of area segments, there may be a refractive index gradient between the two area segments. Alternatively or additionally, when the refractive index changes within an area segment in the plurality of area segments, there may be a refractive index gradient within the area segment.

In some embodiments, the controlling the refractive index of the plurality of area segments of the planar waveguide can define a refractive index gradient over the whole planar waveguide. For example, the plurality of area segments may comprise a large number of area segments and there may be a small gradient between each two adjacent area segments. Thus, the refractive index can change effectively continuously over the whole planar waveguide.

For example, in the embodiment of FIG. 2, the refractive index of the planar waveguide 201 may change from the first segment 210 to the second segment 211, from the second segment 211 to the third segment 212, and/or from the third segment 212 to the fourth segment 213.

According to an embodiment, the controlling the refractive index of the plurality of area segments of the planar waveguide defines at least one gradient in a direction perpendicular to a surface the planar waveguide.

The direction perpendicular to the surface of the planar waveguide 201 may refer to the thickness direction. The direction perpendicular to the surface of the planar waveguide 201 may also be referred to as a direction parallel with a normal direction of the surface of the planar waveguide 201.

The at least one gradient in a direction perpendicular to a surface the planar waveguide may be due to, for example, substance concentration gradient in the direction perpendicular to a surface the planar waveguide 201 and/or attenuation of the electromagnetic radiation and/or of the heat in the direction perpendicular to a surface the planar waveguide 201.

In some other embodiments, the refractive index may be constant or substantially constant in the direction perpendicular to a surface the planar waveguide 201.

According to an embodiment, the method 100 further comprises, after the controlling 102 the refractive index of the plurality of area segments of the planar waveguide, coating the planar waveguide with a reflective coating, wherein the reflective coating is reflective at least to the electromagnetic radiation used to control the refractive index of the plurality of area segments of the planar waveguide.

The reflective coating can, for example, protect the planar waveguide 201 from electromagnetic radiation so that the refractive index of the planar waveguide 201 does not change due to, for example, exposure to UV and/or IR radiation from the sun or other sources when the planar waveguide 201 is in use.

FIG. 3 illustrates a schematic representation of a planar waveguide comprising at least one diffractive grating according to an embodiment.

According to an embodiment, at least one area segment of the plurality of area segments comprises at least one diffractive grating.

For example, in the embodiment of FIG. 3, the plurality of area segments comprises a first area segment 310 comprising a first diffractive grating 320 and a second area segment 311 comprising a second diffractive grating 321. The first area segment 310 and the second area segment 311 are bounded in the width directions. The rest of the planar waveguide 201 not belonging to the first area segment 310 or to the second area segment 311 may be considered a third area segment.

The method 100 can be used to, for example, control/change the refractive index of the planar waveguide 201 in the first area segment 310 and/or in the second area segment 311 while not changing the refractive index of the planar waveguide 201 in other areas. For example, other areas of the planar waveguide 201 may be masked and/or the electromagnetic radiation exposure and/or heat exposure can be concentrated only to the first area segment 310 and/or to the second area segment 311. Alternatively, the opposite can be performed if the refractive index of the planar waveguide 201 needs to be changed only outside the first area segment 310 and/or the second area segment 311.

Herein, a diffractive grating may refer to an optical element the operation of which is based on diffraction of light. Generally, a diffractive grating may comprise structural features with at least one dimension of the order of the wavelengths of visible light, for example, at least one dimension less than one micrometre. A diffractive grating may comprise, for example, a one- and two-dimensional diffraction grating, which may be implemented as a single-region diffraction grating or as multi-region diffraction grating. Diffractive gratings may be implemented as, for example, surface relief gratings or volume holographic gratings, and they may be configured to function as transmission- and/or reflection-type diffraction gratings.

For example, in the embodiment of FIG. 3, the first diffractive grating 320 and the second diffractive grating 321 comprise one-dimensional diffractive gratings comprising grooves/ridges defining the diffractive gratings. These are only exemplary and the at least one diffractive grating may also be implemented in various other ways.

Herein, a diffractive grating may also be referred to as a diffraction grating, an optical diffractive grating, an optical diffraction grating, a surface-relief structure, a surface-relief grating, or similar.

The at least one diffractive grating may comprise, for example, an in-coupling structure for coupling light into the planar waveguide 201 and/or an out-coupling structure for coupling light out of the planar waveguide 201. Alternatively or additionally, the at least one diffractive grating may be configured to control light propagating inside the planar waveguide 201 in various ways.

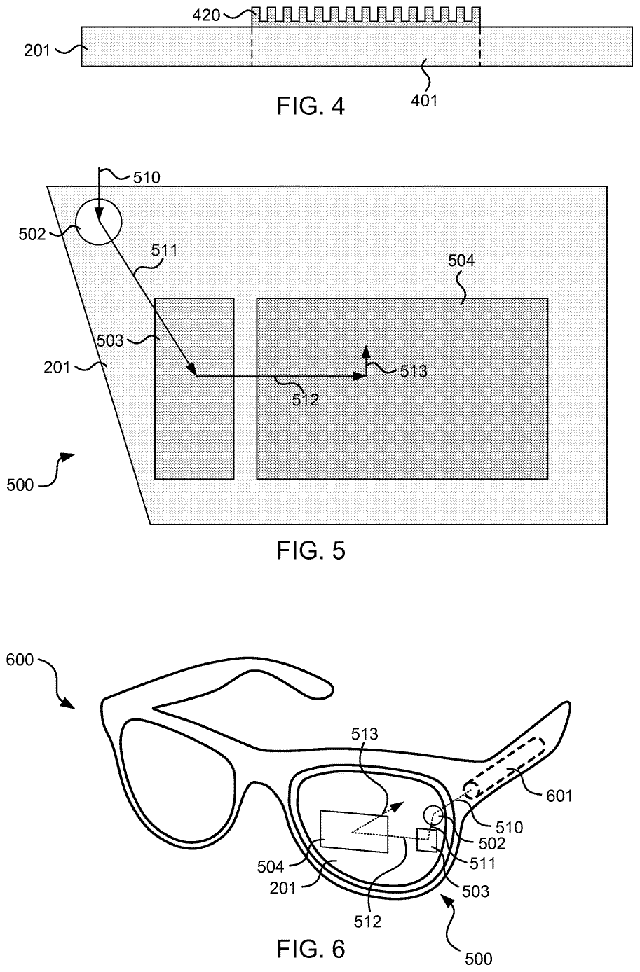

FIG. 4 illustrates a cross-sectional representation of a planar waveguide comprising a diffractive grating according to an embodiment.

According to an embodiment, the controlling the refractive index of the plurality of area segments of the planar waveguide comprises controlling a refractive index of the at least one diffractive grating and/or controlling a refractive index of the planar waveguide in an area segment corresponding to the at least one diffractive grating.

Alternatively or additionally, the controlling the refractive index of the plurality of area segments of the planar waveguide comprises controlling a refractive index of the planar waveguide in an area segment not corresponding to the at least one diffractive grating.

By controlling the refractive index of the at least one diffractive grating 420 and/or of the planar waveguide in an area segment 401 corresponding to the at least one diffractive grating 420, diffractive properties of the at least one diffractive grating 420 can be controlled.

The area segment 401 corresponding to the at least one diffractive grating 420 may refer to, for example, an area segment of the planar waveguide 201 that is covered by the at least one diffractive grating 420. Such an area segment may also be referred to as an area segment under the at least one diffractive grating 420 or similar.

Any disclosure herein about controlling the refractive index of the planar waveguide 201 may also apply to controlling the refractive index of the at least one diffractive grating 420.

According to an embodiment, the at least one diffractive grating comprises a substance sensitive to the electromagnetic radiation and/or to the heat and/or a coating sensitive to the electromagnetic radiation and/or to the heat.

FIG. 5 illustrates a schematic representation of a display structure according to an embodiment.

According to an embodiment, a display structure 500 comprises a planar waveguide 201 obtained by the method 100.

The display structure 500 may further comprise an in-coupling (IC) structure 502 configured to couple a set of input beams 510 into the planar waveguide 201 as a set of in-coupled beams 511.

The IC structure 502 may comprise, for example, a diffractive grating on a surface of the planar waveguide 201.

The display structure 500 may further comprise an exit pupil expansion (EPE) structure 503 configured to receive the set of in-coupled beams 511 and to diffract the set of in-coupled beams 511 in a plurality of directions, producing a set of diffracted beams 512.

It should be appreciated that the set of diffracted beams 512 illustrated in the embodiment of FIG. 5 are only illustrative. In practical embodiments, the EPE structure 503 can diffract the set of in-coupled beams 511 in a plurality of directions in a much more complex manner and the set of diffracted beams 512 can interact with the EPE structure 503 a plurality of times.

The display structure 500 may further comprise an out-coupling (OC) structure 504 configured to receive, from the EPE structure 503, at least the set of diffracted beams 512 and to out-couple at least the set of diffracted beams 512 from the planar waveguide 201 as a set of output beams 513.

The set of output beams 513 may represent, for example, an expanded version of the image formed by the set of input beams 510.

The set of in-coupled beams 511 and the set of diffracted beams 512 can be guided inside the planar waveguide 201 via total internal reflection (TIR). Thus, the guiding can be tuned by controlling the refractive index of the planar waveguide 201 using the method 100.

The IC structure 502, the EPE structure 503 and/or the OC structure 504 may comprise, for example, a diffractive grating on a surface of the planar waveguide 201. The IC structure 502 may couple the set of input beams 510 into the planar waveguide 201 via diffraction. The EPE structure 503 may expand the image corresponding to the set of in-coupled beams 511 via diffraction. The OC structure 504 may out-couple the set of diffracted beams 512 from the planar waveguide 201 via diffraction. The diffractive properties of the IC structure 502, of the EPE structure 503, and/or of the OC structure 504 may be controlled using the method 100.

FIG. 6 illustrates a schematic representation of a display device according to an embodiment.

According to an embodiment, a display device 600 comprises the display structure 500.

According to an embodiment, the display device 600 is implemented as a see-through display device.

According to an embodiment, the display device 600 is implemented as a head-mounted display device.

For example, in the embodiment of FIG. 6, the display device 600 is implemented as a smart glasses. The planar waveguide 201 can correspond to a lens of such smart glasses. Such smart glasses may be used to, for example, implement augmented reality (AR) and/or virtual reality (VR) functionality.

In the embodiment of FIG. 6, the set of input beams 510 may be generated by, for example, an optical engine 601, such as a scanner-based optical engine. The set of input beams 510 may represent an image generated by, for example, such an optical engine. The display structure 500 of the display device 600 can direct the set of output beams 513 representing the image generated by the optical engine 601 into the eye of a user.

Any range or device value given herein may be extended or altered without losing the effect sought. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. A method (100) for controlling a refractive index of a planar waveguide, the method comprising:
providing (101) a planar waveguide comprising a plurality of area segments; and
controlling (102) a refractive index of the plurality of area segments of the planar waveguide by exposing the planar waveguide to a plurality of electro-magnetic radiation exposures corresponding to the plurality of area segments and/or exposing the planar waveguide to a plurality of heat exposures corresponding to the plurality of area segments;
wherein the planar waveguide comprises a substance sensitive to the electromagnetic radiation and/or to the heat.

2. The method (100) according to claim 1, wherein the exposing the planar waveguide to the plurality of electromagnetic radiation exposures corresponding to the plurality of area segments and/or the exposing the planar waveguide to the plurality of heat exposures corresponding to the plurality of area segments comprises at least one of:
masking at least one area segment of the plurality of area segments;
varying an intensity of the electromagnetic radiation between the plurality of area segments;
varying an intensity of the heat between the plurality of area segments; and/or
varying a wavelength of the electromagnetic radiation between the plurality of area segments.

3. The method (100) according to claim 1 or claim 2, wherein the electromagnetic radiation comprises ultraviolet radiation and/or infrared radiation.

4. The method (100) according to any preceding claim, wherein the planar waveguide further comprises a coating sensitive to the electromagnetic radiation and/or to the heat.

5. The method (100) according to any claim 4, wherein the electromagnetic radiation comprises ultra-violet radiation and the substance and/or the coating comprises at least one of: titanium dioxide, germanium dioxide, germanium, and/or boron.

6. The method (100) according to any preceding claim, wherein at least one area segment of the plurality of area segments comprises at least one diffractive grating.

7. The method (100) according to claim 6, wherein the controlling the refractive index of the plurality of area segments of the planar waveguide comprises controlling a refractive index of the at least one diffractive grating and/or controlling a refractive index of the planar waveguide in an area segment corresponding to the at least one diffractive grating.

8. The method (100) according to any preceding claim, wherein the controlling the refractive index of the plurality of area segments of the planar waveguide defines at least one refractive index gradient over the planar waveguide.

9. The method (100) according to any preceding claim, wherein the controlling the refractive index of the plurality of area segments of the planar waveguide defines at least one gradient in a direction perpendicular to a surface the planar waveguide.

10. The method (100) according to any preceding claim, the method further comprising, after the controlling the refractive index of the plurality of area segments of the planar waveguide, coating the planar waveguide with a reflective coating, wherein the reflective coating is reflective at least to the electro-magnetic radiation used to control the refractive index of the plurality of area segments of the planar waveguide.

11. A display structure comprising a planar waveguide obtained by the method according to any preceding claim.

12. A display device comprising the display structure according to claim 11.

13. A display device according to claim 12 implemented as a see-through display device.

14. A display device according to claim 12 or claim 13 implemented as a head-mounted display device.
